(19) United States
(12) Patent Application Publication
(10) Pub. No.: US 2010/0032822 A1
(43) Pub. Date: Feb. 11, 2010

(54) CHIP PACKAGE STRUCTURE

(75) Inventors: CHEN-KAI LIAO, Pingtung County (TW); CHENG-YI WENG, Kaohsiung City (TW); MENG-JEN WANG, Pingtung County (TW)

Correspondence Address: J C PATENTS, 4 VENTURE, SUITE 250, IRVINE, CA, 92618, US

(73) Assignee: Advanced Semiconductor Engineering, Inc., Kaohsiung (TW)

(21) Appl. No.: 12/512,319

(22) Filed: Jul. 30, 2009

(30) Foreign Application Priority Data
Aug. 7, 2008 (TW) 97130106

(51) Int. Cl. H01L 23/498

(52) U.S. Cl. 257/690; 257/E23.069

(57) ABSTRACT

A chip package structure including a first substrate, a chip, a second substrate, a plurality of conductive wires, a plurality of solder balls and a molding compound is provided. The chip is disposed on the first substrate. The second substrate disposed on the chip has an upper surface and a lower surface, in which a distance of the lower surface relative to the chip is smaller than that of the upper surface relative to the chip. The upper surface has a ball mounting surface and a wire bonding surface. A distance between the wire bonding surface and the first substrate is smaller than that between the ball mounting surface and the first substrate. The conductive wires connect the wire bonding surface to the first substrate. The solder balls are disposed on the ball mounting surface. The molding compound is disposed on the first substrate.

### CROSS-REFERENCE TO RELATED APPLICATION

This application claims the priority benefit of Taiwan application serial no. 97130106, filed Aug. 7, 2008. The entirety of the above-mentioned patent application is hereby incorporated by reference herein and made a part of this specification.

### BACKGROUND OF THE INVENTION

1. Field of the Invention

The present invention generally relates to a chip package structure, in particular, to a chip package structure applicable to a package-on-package (POP) process.

2. Description of Related Art

The chip package technique aims at providing sufficient signal paths, heat dissipation paths, and structure protection for chips. In the conventional art, a 3D packaging manner of package-on-package (POP) is proposed, which is capable of reducing a carrying area occupied by a plurality of chip packaging structures on a circuit board by stacking the chip package structures together.

FIG. 1 is a schematic cross-sectional view of a conventional chip package structure applied to a POP process. Referring to FIG. 1, in a chip package structure 100, a chip 110 is disposed on a first substrate 120, and a second substrate 130 is disposed on the chip 110 via an adhesive layer 180 disposed therebetween. The second substrate 130 is electrically connected to the first substrate 120 via a plurality of first conductive wires 140, and the chip 110 is electrically connected to the first substrate 120 via a plurality of bump 150.

In detail, the first conductive wires 140 are used to connect a surface 132 of the second substrate 130 far away from the chip 110 to the first substrate 120, so that a portion of the first conductive wires 140 are located on the surface 132. Furthermore, pads 160 are also disposed on the surface 132 of the second substrate 130.

In addition, a molding compound 170 disposed on the first substrate 120 encapsulates the chip 110, a portion of the second substrate 130 and the first conductive wires 140, but has an opening 172 exposing the pads 160.

It should be noted that, the thickness of the portion of the molding compound 170 located on the surface 132 is limited by a distance of the conductive wires 140 relative to the surface 132 so the thickness of the molding compound 170 is hard to be reduced. Therefore, the thickness of the chip package structure 100 is great. Besides, the molding compound 170 having the opening 172 is formed by a special mold so the fabricating cost of the molding compound 170 is high.

### SUMMARY OF THE INVENTION

Accordingly, the present invention is directed to a chip package structure, which is suitable for reducing the solder extrusion possibility.

The present invention provides a chip package structure, which includes a first substrate, a chip, a second substrate, a plurality of first conductive wires, a plurality of solder balls, and a molding compound. The chip is disposed on the first substrate, and is electrically connected to the first substrate. The second substrate disposed on the chip has an upper surface and a lower surface, in which a distance of the lower surface relative to the chip is smaller than that of the upper surface relative to the chip. The upper surface has a ball mounting surface and a wire bonding surface. A distance between the wire bonding surface and the first substrate is smaller than a distance between the ball mounting surface and the first substrate. The first conductive wires are used to connect the wire bonding surface to the first substrate, so as to electrically connect the second substrate to the first substrate. The first solder balls are disposed on the ball mounting surface, and are electrically connected to the second substrate. The molding compound disposed on the first substrate encapsulates the chip, the second substrate and the solder balls, and exposes a top end of each of the first solder balls.

In an embodiment of the present invention, a maximum distance of the first conductive wires relative to the first substrate is smaller than a distance of the top end of each of the first solder balls relative to the first substrate.

In an embodiment of the present invention, a maximum distance of the first conductive wires relative to the first substrate is smaller than a distance of the ball mounting surface relative to the first substrate.

In an embodiment of the present invention, the chip package structure further includes a plurality of second conductive wires, for connecting the chip to the first substrate, so as to electrically connect the chip to the first substrate.

In an embodiment of the present invention, the chip package structure further includes an adhesion layer disposed between the second substrate and the chip.

In an embodiment of the present invention, the adhesion layer encapsulates a portion of each of the second conductive wires.

In an embodiment of the present invention, the chip package structure further includes a spacer disposed between the second substrate and the chip.

In an embodiment of the present invention, the chip package structure further includes a plurality of bumps, disposed between the chip and the first substrate, so as to electrically connect the chip to the first substrate.

In an embodiment of the present invention, a top end of each of the first solder balls are substantially flush with a top surface of the molding compound.

In an embodiment of the present invention, the chip package structure further includes a plurality of second solder balls disposed on a surface of the first substrate away from the chip.

In an embodiment of the present invention, the ball mounting surface and the wire bonding surface are substantially parallel but are not coincided with each other.

In an embodiment of the present invention, the second substrate further includes a connecting surface extending between the wire bonding surface and the ball mounting surface, and connecting the ball mounting surface to the wire bonding surface.

In an embodiment of the present invention, a distance exists between the ball mounting surface and a top surface of the molding compound.

In an embodiment of the present invention, the distance existing between the ball mounting surface and the top surface is substantially equal to a height of each of the first solder balls.

In the present invention, since the distance between the wire bonding surface of the second substrate and the first substrate is smaller than the distance between the ball mounting surface and the first substrate, the maximum distance of the first conductive wires relative to the first substrate may be reduced, such that the first conductive wires are made to be away from a top surface of the molding compound to be grinded.

Therefore, when the molding compound is grinded to expose the first solder balls, it is not easy for the molding compound to expose the first conductive wires, which is helpful to reduce the thickness of the portion of the molding compound located on the ball mounting surface for encapsulating the first solder balls, thereby reducing the solder extrusion possibility.

### BRIEF DESCRIPTION OF THE DRAWINGS

The accompanying drawings are included to provide a further understanding of the invention, and are incorporated in and constitute a portion of this specification. The drawings illustrate embodiments of the invention and, together with the description, serve to explain the principles of the invention.

FIG. 1 is a schematic cross-sectional view of a conventional chip package structure applied to a POP process.

FIG. 2 is a schematic cross-sectional view of a chip package structure according to an embodiment of the present invention.

FIG. 3 is a schematic cross-sectional view of a chip package structure according to another embodiment of the present invention.

FIG. 4 is a schematic cross-sectional view of a chip package structure according to still another embodiment of the present invention.

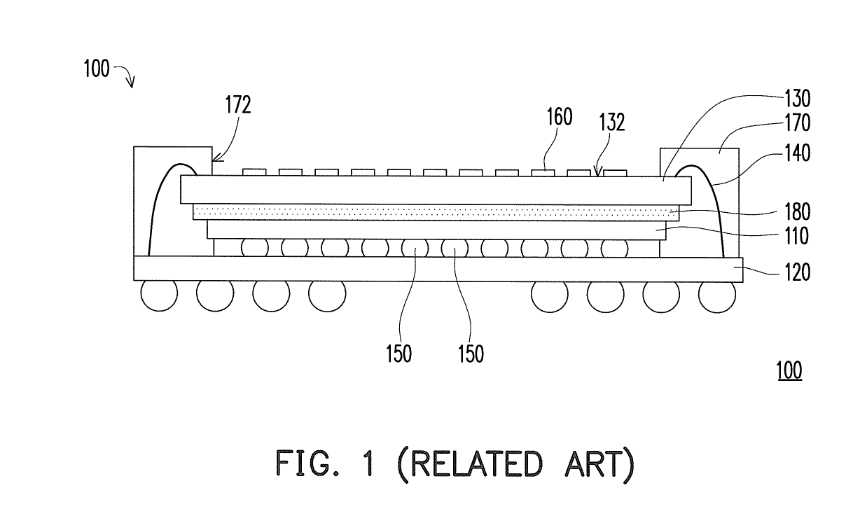

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

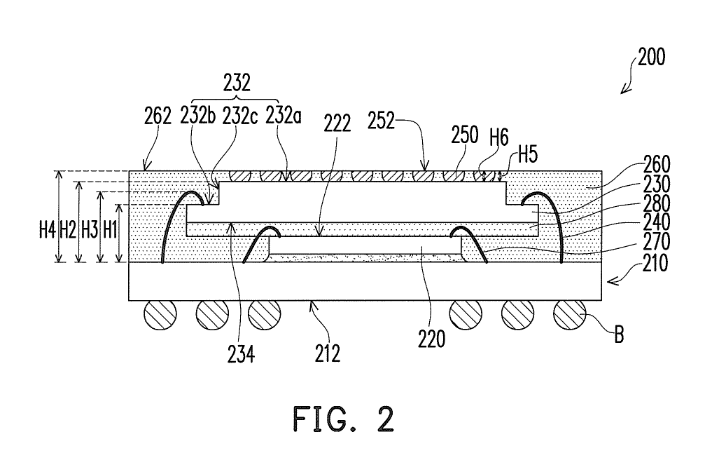

FIG. 2 is a schematic cross-sectional view of a chip package structure according to an embodiment of the present invention. Referring to FIG. 2, a chip package structure 200 of this embodiment includes a first substrate 210, a chip 220, a second substrate 230, a plurality of first conductive wires 240, a plurality of first solder balls 250, and a molding compound 260. The first substrate 210 is used to carry the chip 220, the second substrate 230, the first conductive wires 240, the first solder balls 250, and the molding compound 260.

The chip 220 is disposed on the first substrate 210, and is electrically connected to the first substrate 210. In this embodiment, the chip 220 may be electrically connected to the first substrate 210 via a plurality of second conductive wires 270, and the second conductive wires 270 are used to connect the chip 220 to the first substrate 210.

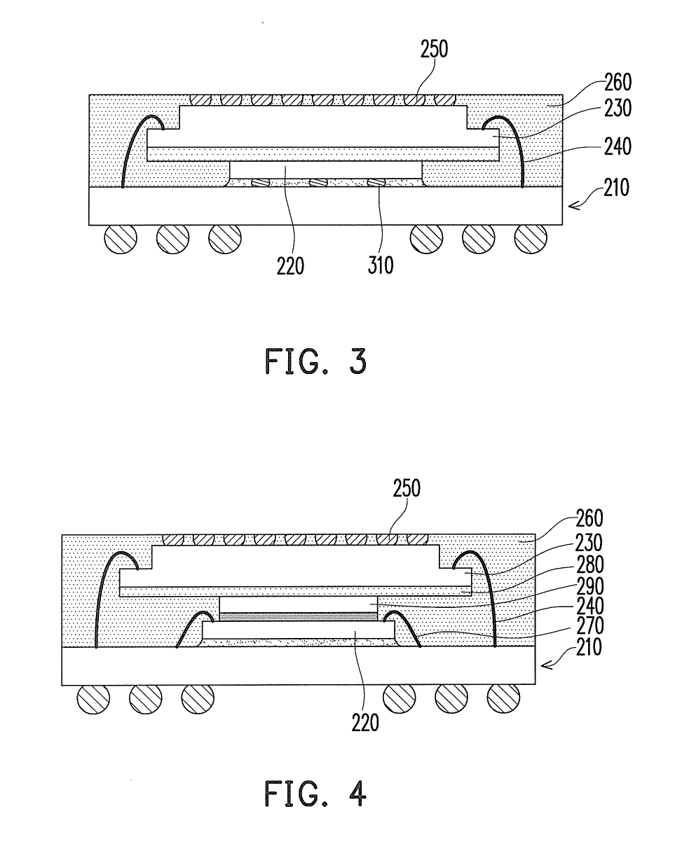

FIG. 3 is a schematic cross-sectional view of a chip package structure according to another embodiment of the present invention. Referring to FIG. 3, in this embodiment, the chip 220 may also be electrically connected to the first substrate 210 via a plurality of bumps 310 disposed between the chip 220 and the first substrate 210.

Referring to FIG. 2 again, the second substrate 230 is disposed on the chip 220, and has an upper surface 232 and a lower surface 234, in which a distance of the lower surface 234 relative to a upper surface 222 of the chip 220 is smaller than that of the upper surface 232 relative to the upper surface 222 of the chip 220. The upper surface 232 has a ball mounting surface 232a and a wire bonding surface 232b, and a distance H1 between the wire bonding surface 232b and the first substrate 210 is smaller than a distance H2 between the ball mounting surface 232a and the first substrate 210.

The ball mounting surface 232a and the wire bonding surface 232b may be substantially parallel but not coincided with each other, and the second substrate 230 may further include a connecting surface 232c extending between the wire bonding surface 232b and the ball mounting surface 232a and connecting the ball mounting surface 232a to the wire bonding surface 232b, such that a boundary between the ball mounting surface 232a and the wire bonding surface 232b turns to be step-shaped.

The first conductive wires 240 are used to connect the wire bonding surface 232b to the first substrate 210, so as to electrically connect the second substrate 230 to the first substrate 210, and the first solder balls 250 are disposed on the ball mounting surface 232a, and are electrically connected to the second substrate 230.

It should be noted that, different from the conventional art, the distance H1 between the wire bonding surface 232b and the first substrate 210 in this embodiment is smaller than the distance H2 between the ball mounting surface 232a and the first substrate 210. In this embodiment, a maximum distance H3 of the first conductive wires 240 relative to the first substrate 210 may be smaller than a distance H4 of the top ends of the first solder balls 250 relative to the first substrate 210. For example, the maximum distance H3 of the first conductive wires 240 relative to the first substrate 210 may be smaller than a distance H2 of the ball mounting surface 232a relative to the first substrate 210 and greater than the distance H1 of the wire bonding surface 232b relative to the first substrate 210.

The molding compound 260 disposed on the first substrate 210 encapsulates the chip 220, the second substrate 230, the first conductive wires 240, the first solder balls 250, and the second conductive wires 270, and exposes the top end of each of the first solder balls 250. In this embodiment, a distance H5 exists between the ball mounting surface 232a and a top surface 262 of the molding compound 260 and the distance H5 is substantially equal to a height H6 of each of the first solder balls 250. In this embodiment, a top end 252 of each of the first solder balls 250 is substantially flush with the top surface of the molding compound 260. In other words, the top end 252 and the top surface of the molding compound 260 are substantially connected. Furthermore, in this embodiment, the top end 252 may be coplanar with the top surface 262 of the molding compound 260.

In this embodiment, the distance H1 between the wire bonding surface 232b and the first substrate 210 is smaller than the distance H2 between the ball mounting surface 232a and the first substrate 210, so as to reduce the maximum distance H3 of the first conductive wires 240 relative to the first substrate 210. Therefore, when the molding compound 260 is grinded to expose the first solder balls 250, it is not easy for the molding compound 260 to expose the first conductive wires 240.

As compared with the conventional art, a portion of the molding compound 260 located on the ball mounting surface 232a has a relatively small thickness. Therefore, during the process of assembling the chip package structure 200 to another chip package structure (not shown) through the first solder balls 250, it is not easy for the molding compound 260 that is expanded upon being heated to extrude a portion of the melted first solder balls 250 out of the top surface of the molding compound 260, so as to reduce the solder extrusion possibility.

In this embodiment, in order to dispose the second substrate 230 on the chip 220, an adhesion layer 280 may be disposed between the second substrate 230 and the chip 220, in which the adhesion layer 280 may encapsulate a portion of each of the second conductive wires 270. In addition, in this embodiment, a plurality of second solder balls B may be disposed on a surface 212 of the first substrate 210 away from the chip 220, so as to electrically connect to the exterior.

FIG. 4 is a schematic cross-sectional view of a chip package structure according to still another embodiment of the present invention. Referring to FIG. 4, as compared with the embodiment shown in FIG. 2, in this embodiment, a spacer 290 is further disposed between the second substrate 230 and the chip 220, so as to increase the distance between the chip 220 and the second substrate 230. In this embodiment, the spacer 290 may be a dummy die or a material layer with a coefficient of thermal expansion (CTE) between that of the chip 220 and that of the second substrate 230.

To sum up, in the present invention, the distance between the wire bonding surface of the second substrate and the first substrate is smaller than the distance between the ball mounting surface and the first substrate, so as to reduce the maximum distance of the first conductive wires relative to the first substrate, such that the first conductive wires are made to be far away from a top surface of the molding compound to be grinded.

Therefore, when the molding compound is grinded to expose the first solder balls, the molding compound does not easily expose the first conductive wires. Thus, it is helpful for reducing the thickness of a portion of the molding compound located on the ball mounting surface for encapsulating the first solder balls, thereby reducing the solder extrusion possibility.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package structure, comprising:
a first substrate;
a chip, disposed on the first substrate, and electrically connected to the first substrate;
a second substrate, disposed on the chip, and comprising an upper surface and a lower surface, wherein a distance of the lower surface relative to the chip is smaller than that of the upper surface relative to the chip, the upper surface comprises a ball mounting surface and a wire bonding surface, and a distance between the wire bonding surface and the first substrate is smaller than that between the ball mounting surface and the first substrate;
a plurality of first conductive wires connects the wire bonding surface to the first substrate, so as to electrically connect the second substrate to the first substrate;
a plurality of first solder balls, disposed on the ball mounting surface, and electrically connected to the second substrate; and
a molding compound, disposed on the first substrate and encapsulating the chip, the second substrate and the first solder balls, and exposing a top end of each of the first solder balls.

2. The chip package structure according to claim 1, wherein a maximum distance of the first conductive wires relative to the first substrate is smaller than a distance of the top end of the first solder ball relative to the first substrate.

3. The chip package structure according to claim 1, wherein a maximum distance of the first conductive wires relative to the first substrate is smaller than a distance of the ball mounting surface relative to the first substrate.

4. The chip package structure according to claim 1, further comprising:
a plurality of second conductive wires, connecting the chip to the first substrate, so as to electrically connect the chip to the first substrate.

5. The chip package structure according to claim 4, further comprising:
an adhesion layer, disposed between the second substrate and the chip.

6. The chip package structure according to claim 5, wherein the adhesion layer encapsulates a portion of each of the second conductive wires.

7. The chip package structure according to claim 5, further comprising:
a spacer, disposed between the second substrate and the chip.

8. The chip package structure according to claim 1, further comprising:
a plurality of bumps, disposed between the chip and the first substrate, so as to electrically connect the chip to the first substrate.

9. The chip package structure according to claim 1, wherein the top end of each of the first solder balls are substantially flush with a top surface of the molding compound.

10. The chip package structure according to claim 1, further comprising:
a plurality of second solder balls, disposed on a surface of the first substrate away from the chip.

11. The chip package structure according to claim 1, wherein the ball mounting surface and the wire bonding surface are substantially parallel but not coincided with each other.

12. The chip package structure according to claim 1, wherein the second substrate further comprises:
a connecting surface extending between the wire bonding surface and the ball mounting surface, and connecting the ball mounting surface to the wire bonding surface.

13. The chip package structure according to claim 1, wherein a distance exists between the ball mounting surface and a top surface of the molding compound.

14. The chip package structure according to claim 13, wherein the existing between the ball mounting surface and the top surface of the molding compound is substantially equal to a height of each of the first solder balls.
